(19) United States
(12) Patent Application Publication
(10) Pub. No.: US 2012/0329224 A1
(43) Pub. Date: Dec. 27, 2012

(54) METHOD OF FORMING FINE PATTERN AND METHOD OF MANUFACTURING SEMICONDUCTOR DEVICE

(75) Inventors: Yoo-chul Kong, Seoul (KR); Jin-kwan Lee, Seoul (KR); Gyung-jin Min, Seongnam-si (KR); Seong-soo Lee, Seongnam-si (KR)

(73) Assignee: SAMSUNG ELECTRONICS CO., LTD., Suwon-si (KR)

(21) Appl. No.: 13/495,510

(22) Filed: Jun. 13, 2012

(30) Foreign Application Priority Data
Jun. 23, 2011 (KR) 10-2011-0061322

(51) Int. Cl. H01L 21/308; H01L 21/336

(52) U.S. Cl. 438/268; 438/703; 438/702; 257/E21.232; 257/E21.41

(57) ABSTRACT

A method of forming a fine pattern and a method of manufacturing a semiconductor device. The method of forming a fine pattern includes: forming a hard mask layer on a to-be-etched layer; forming on the hard mask layer a first mask pattern including a plurality of elongated openings that are arranged at predetermined intervals in a first direction and a second direction different from the first direction and are offset from each other in adjacent columns in the second direction; forming on the hard mask layer a second mask pattern including at least two linear openings that each pass through the elongated openings in the adjacent columns and extend in the first direction; forming a hard mask pattern by etching the hard mask layer by using the second mask pattern as an etch mask; and etching the to-be-etched layer by using the hard mask pattern.

### CROSS-REFERENCE TO RELATED APPLICATIONS

This application claims priority under 35 U.S.C. §119 to Korean Patent Application No. 10-2011-0061322, filed on Jun. 23, 2011, in the Korean Intellectual Property Office, the disclosure of which is incorporated herein in its entirety by reference.

### BACKGROUND

Example embodiments of inventive concepts relate to a method of forming a fine pattern and a method of manufacturing a semiconductor device.

Semiconductor apparatuses are getting smaller and may be required to process more data. Accordingly, it is desired to increase a degree of integration of a semiconductor device constituting a semiconductor apparatus and to form a fine pattern in the semiconductor apparatus. Accordingly, there is demand for fine patterns having small widths and small intervals and capable of overcoming the resolution limit of photolithography.

### SUMMARY

Example embodiments of inventive concepts relate a method of forming a fine pattern and/or a method of manufacturing a semiconductor device using the method of forming a fine pattern.

According to example embodiments of inventive concepts, a method of forming a fine pattern includes: forming a hard mask layer on a to-be-etched layer; forming a first mask pattern on the hard mask layer, the first mask pattern defining a plurality of elongated openings that are arranged at intervals in a first direction and a second direction different from the first direction and are offset from each other in adjacent columns in the second direction; forming a second mask pattern on the hard mask layer, the second mask pattern defining at least two linear openings that each pass through the elongated openings of the first mask pattern and extend in the first direction; forming a hard mask pattern by etching the hard mask layer by using the second mask pattern as an etch mask; and etching the to-be-etched layer by using the hard mask pattern as another etch mask.

The plurality of elongated openings may be elongated in the second direction, and the first mask pattern may include a chess board-like arrangement due to the plurality of elongated openings.

The first mask pattern may include a first pattern portion and a second pattern portion adjacent to the first pattern portion. Each of the first pattern portion and the second pattern portion may define one column of the plurality of elongated openings arranged at intervals in the first direction, and the first pattern portion and the second pattern portion may be alternately arranged in the second direction.

In the first mask pattern, the plurality of elongated openings of the first pattern portion and the plurality of elongated openings of the second pattern portion may have different lengths in the second direction.

The second mask pattern may be on end portions of the first pattern portion and the second pattern portion in the second direction.

The first mask pattern may include a stepped portion and the second mask pattern may be thick enough to cover the stepped portion of the first mask pattern.

The second mask pattern may expose a portion of the hard mask layer and a portion of the first mask pattern.

The forming of the hard mask pattern may include forming apertures in portions of the hard mask layer exposed by the first mask pattern and the second mask pattern, and the etching of the to-be-etched layer may include forming holes in portions of the to-be etched layer exposed by the hard mask pattern.

The holes of the to-be etched layer may be arranged in a zigzag fashion in the first direction.

The first mask pattern, the second mask pattern, and the hard mask layer may include materials having etch selectivities with respect to one another.

The hard mask layer may include silicon oxide, the first mask pattern may include silicon nitride, and the second mask pattern may include a carbon-containing material.

The forming of the first mask pattern may include forming a first mask layer and forming an anti-reflective layer on the first mask layer, and the forming of the second mask pattern may include forming a second mask layer and forming an anti-reflective layer on the second mask layer.

According to example embodiments of inventive concepts, a method of manufacturing a semiconductor device includes: alternately stacking interlayer sacrificial layers and interlayer insulating layers on a substrate; forming first openings, which pass through the interlayer sacrificial layers and the interlayer insulating layers to be connected to the substrate, by using the foregoing method of forming a fine pattern; and forming channel regions in the first openings.

The method may further include: forming buried insulating layers on the channel regions to fill the first openings; forming second openings, which pass through the interlayer sacrificial layers and the interlayer insulating layers to be connected to the substrate, between the channel regions; forming side openings by removing portions of the interlayer sacrificial layers exposed through the second openings, the side openings extending from the second openings to partially expose the channel regions and interlayer insulating layers; forming gate dielectric layers in the side openings; and forming gate electrodes including a memory cell transistor electrode and a select transistor electrode on the gate dielectric layers to cover the side openings.

The hard mask layer may include: a first hard mask layer containing polysilicon and on the interlayer sacrificial layers; a second hard mask layer containing a carbon-containing material and on the first hard mask layer; and a third hard mask layer containing silicon oxide and on the second hard mask layer.

According to example embodiments, a method of forming a fine pattern includes: forming a first mask pattern on a lower structure, the first mask pattern including at least one first pattern portion, the first pattern portion defining a plurality of first openings that are spaced apart from each at intervals in a first direction and elongated in a second direction, the first and the second direction being non-parallel; forming a second mask pattern on the first mask pattern, the second mask pattern defining a plurality of first linear openings, each of the first linear openings being elongated in the first direction and intersecting at least one of the first openings of the first mask pattern; and etching a portion of the lower structure exposed where the first linear openings of the second mask pattern intersect the first openings of the first mask pattern.

The lower structure may include at least one hard mask film on a to-be etch layer. The etching a portion of the lower structure may include forming a hard mask pattern by etching through the at least one hard mask film by using the second mask pattern as an etch mask, and etching the portions of the to-be etched layer by using the hard mask pattern as another etch mask.

The first mask pattern may include a plurality of the first pattern portions, and a plurality of second pattern portions arranged in between the plurality of first pattern portions along the second direction. Each second pattern portion may define a plurality of second openings that are spaced apart from each other at intervals in the first direction, elongated in the second direction, and offset along the first direction from the first openings in adjacent first pattern portions. The second mask pattern may include a plurality of second linear openings. Each of the second linear openings may be elongated in the first direction and intersect at least one of the second openings of the second mask pattern. The method may further include etching a part of the lower structure exposed where the second linear openings of the second mask intersect the second openings of the first mask pattern.

The method may include etching the portion of the lower structure and the part of the lower structure simultaneously.

According to example embodiments, a method of forming pillar openings may include alternately stacking interlayer sacrificial layers and interlayer insulating layers on a substrate, and using the foregoing method to form a plurality of first and second pillar openings through the interlayer sacrificial layers and the interlayer insulating layers to expose regions of the substrate. The lower structure may correspond to the interlayer sacrificial layers and the interlayer insulating layers alternately stacked on the substrate. The first pillar openings may correspond to the portion of the lower structure etched where the first linear openings of the second mask pattern intersect the first openings of the first mask pattern. The second pillar openings may correspond to the part of the lower structure etched where the second linear openings of the second mask pattern intersect the second openings of the first mask pattern.

### BRIEF DESCRIPTION OF THE DRAWINGS

The foregoing and other features and advantages of inventive concepts will be more clearly understood from the following detailed description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIGS. 1A through 1F are views illustrating layouts of mask patterns for forming a fine pattern, according to example embodiments of inventive concepts;

FIGS. 2A through 9B are views illustrating a method of forming a fine pattern, according to example embodiments of inventive concepts;

FIG. 10 is an equivalent circuit diagram illustrating a memory cell array of a semiconductor device manufactured by the method of FIGS. 2A through 9B;

FIG. 11 is a perspective view illustrating a three-dimensional (3D) structure of memory cell strings of a semiconductor device according to example embodiments of inventive concepts; and

FIGS. 12 through 17 are cross-sectional views illustrating a method of manufacturing the semiconductor device of FIG. 11, according to example embodiments of inventive concepts.

### DETAILED DESCRIPTION OF THE EMBODIMENTS

Hereinafter, the example embodiments of inventive concepts will be described more fully with reference to the accompanying drawings, in which some example embodiments are shown. Example embodiments may, however, be embodied in many different forms and should not be construed as being limited to the embodiments set forth herein; rather these example embodiments are provided so that this disclosure will be thorough and complete, and will fully convey the concept of example embodiments of inventive concepts to one of ordinary skill in the art. In the drawings, the thicknesses of layers and regions may be exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

In the drawings, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. Furthermore, various elements and regions in the drawings are schematically drawn, and thus are not limited to their relative sizes or intervals in the attached drawings. As used herein, the term “and/or” includes any and all combinations of one or more of the associated listed items. Expressions such as “at least one of,” when preceding a list of elements, modify the entire list of elements and do not modify the individual elements of the list.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

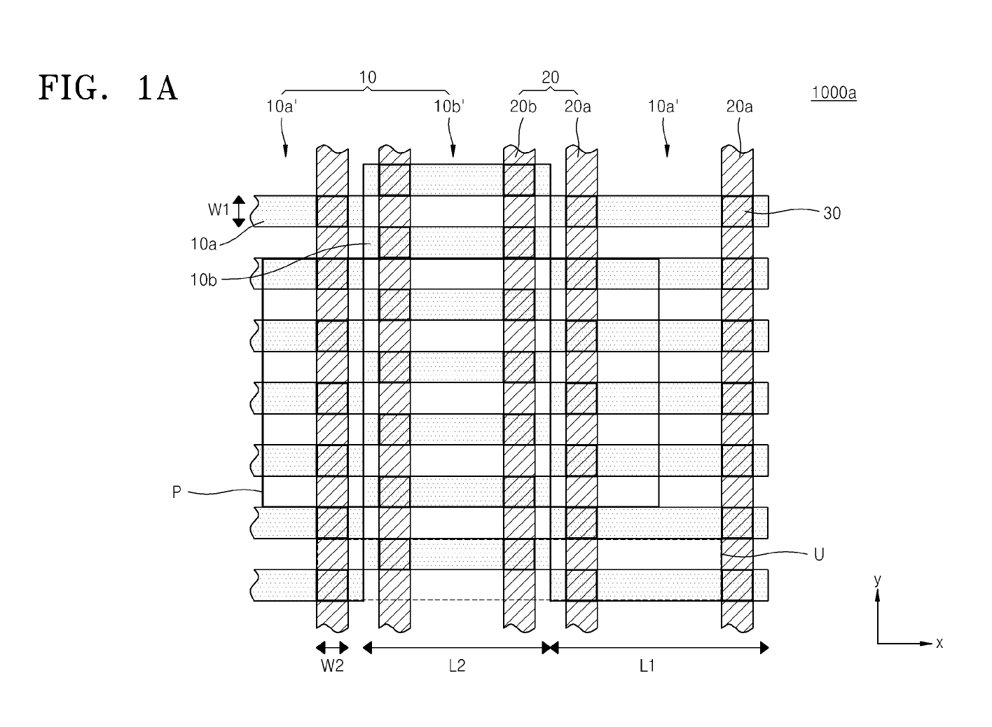

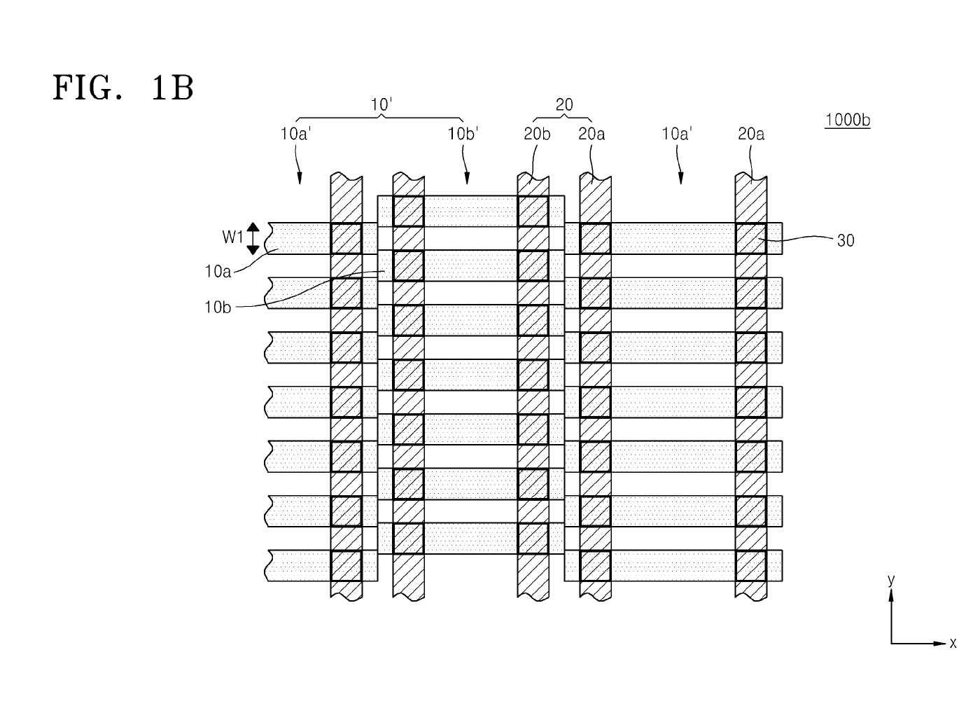

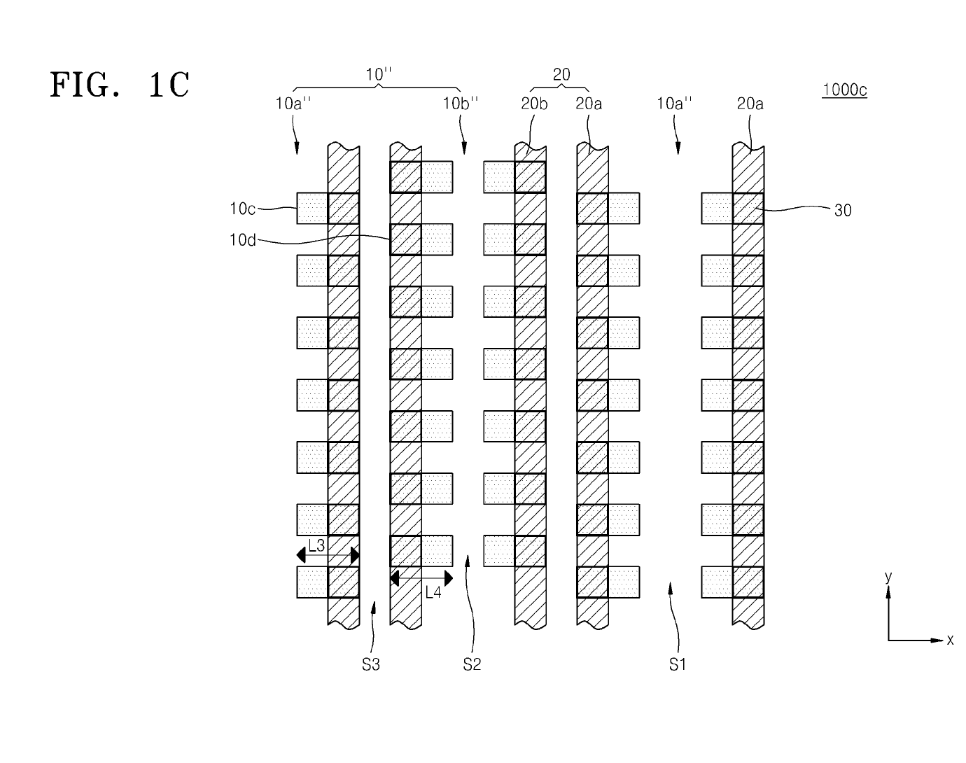

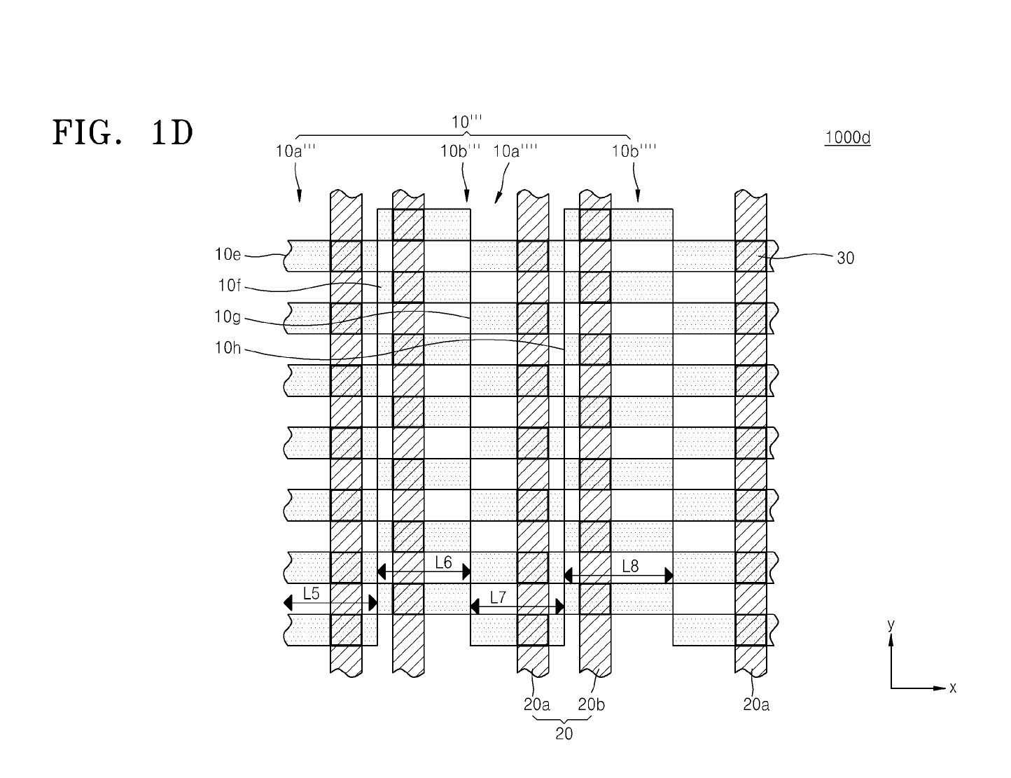

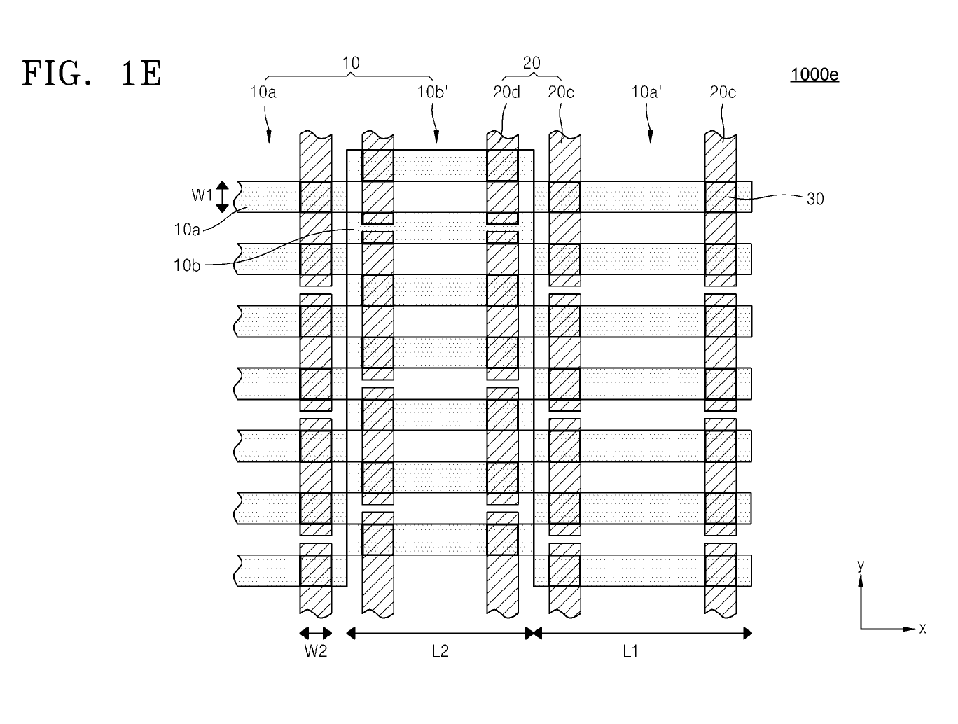

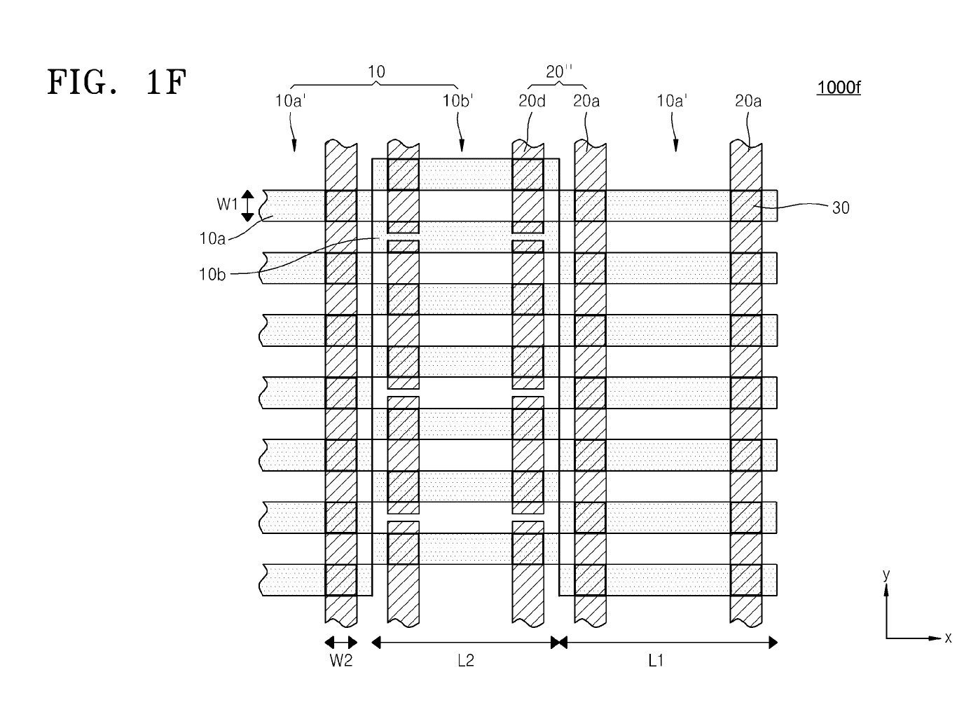

FIGS. 1A through 1F are views illustrating layouts of mask patterns 1000a, 1000b, 1000c, 1000d, 1000e, and 1000f for forming a fine pattern, according to example embodiments of inventive concepts.

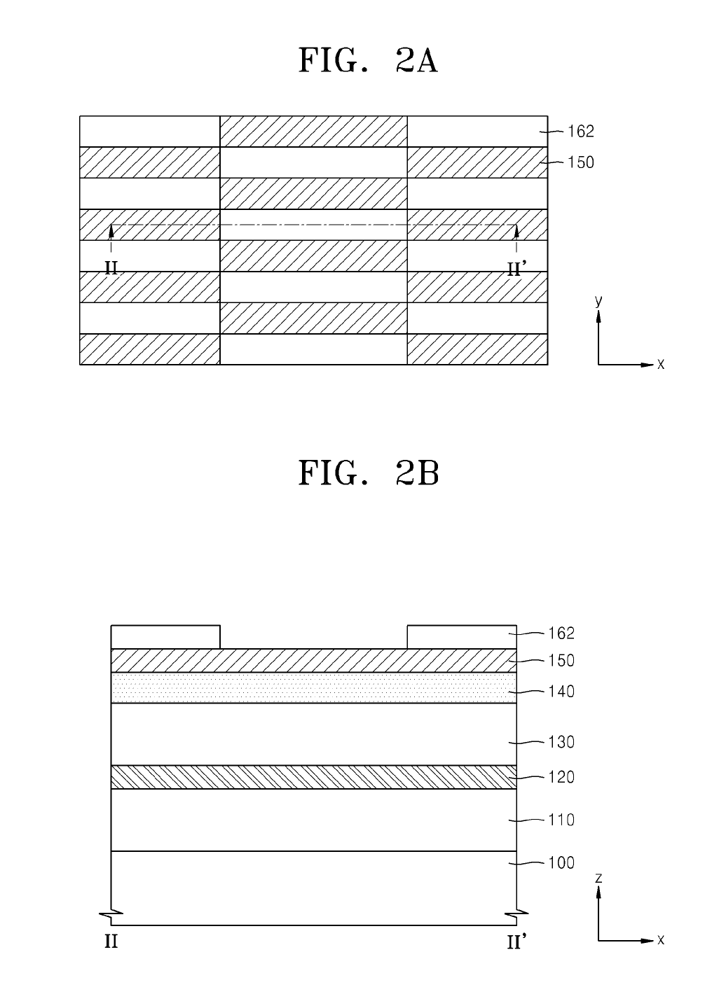

Referring to FIG. 1A, the mask pattern 1000a may include a first mask pattern 10 and a second mask pattern 20. Each of the first mask pattern 10 and the second mask pattern 20 may be manufactured as a separate mask, for example, a photomask, and may be used to form a fine pattern as described below with reference to FIGS. 2A through 9B. The first mask pattern 10 and the second mask pattern 20 shown in FIGS. 1A through 1D may be engraved. That is, the first mask pattern 10 and the second mask pattern 20 may correspond to open regions. Accordingly, due to etching, portions of a lower layer corresponding to the first mask pattern 10 and the second mask pattern 20 may be exposed.

The first mask pattern 10 may include a first pattern portion 10a′ and a second pattern portion 10b′, and the first pattern portion 10a′ and the second pattern portion 10b′ may respectively include a plurality of elongated patterns 10a and 10b. The term ‘an elongated shape’ refers to a relatively short linear shape including a quadrangular shape and an oval shape having a long axis in one direction.

The plurality of elongated patterns 10a and 10b of the first and second pattern portions 10a′ and 10b′ may be arranged at desired (or alternatively predetermined) intervals in a y-direction. Each of the elongated patterns 10a and 10b may have a first width W1. The first and second pattern portions 10a′ and 10b′ may be alternately arranged in an x-direction and may be offset from each other by a desired (or alternatively predetermined) length to form a checkered pattern or a chessboard-like pattern as a whole. The desired (or alternatively predetermined) length by which the first and second pattern portions 10a′ and 10b′ are offset from each other may be equal to the first width W1, or less than or greater than the first width W1.

Each of the elongated patterns 10a of the first pattern portion 10a′ may have a first length L1, and each of the elongated patterns 10b of the second pattern portion 10b′ may have a second length L2. The first length L1 and the second length L2 may be different or may be the same. If the first length L1 and the second length L2 are the same, the second pattern portion 10b′ may be obtained by moving the first pattern portion 10a′ by the first width W1 in the y-direction.

The second mask pattern 20 may include a first line 20a that extends across the first pattern portion 10a′, and a second line 20b that extends across the second pattern portion 10b′. The first line 20a and the second line 20b may be spaced apart from each other by a desired (or alternatively predetermined) length in the x-direction from a border between the first and second pattern portions 10a′ and 10b′ and may extend in the y-direction. The first lines 20a may be disposed on both end parts of the first pattern portion 10a′ and the second lines 20b may be disposed on both end parts of the second pattern portion 10b′ in the x-direction.

Holes 30 may be defined at intersections between the first mask pattern 10 and the second mask pattern 20. This is because the holes 30 may be formed in portions of a lower layer where the first mask pattern 10 and the second mask pattern 20 are commonly exposed. The holes 30 may be formed in zig-zag in a plurality of columns in the y-direction. In FIGS. 1A through 1D, the columns may be formed such that the columns are symmetrical with adjacent columns about a pattern portion.

A basic unit U of the mask pattern 1000a of FIG. 1A may be repeatedly formed in the x-direction and the y-direction. A method of forming a fine pattern of FIGS. 2A through 9B will be explained below with reference to a portion P of FIG. 1A.

Referring to FIG. 1B, the elongated patterns 10a and 10b of the first mask pattern 10′ are more closely arranged in the y-direction than in the first mask pattern 10 in FIG. 1A. If a semiconductor device to which a pattern is to be formed is required to have a high degree of integration, the holes 30 may be formed at intersections between the second mask pattern 20 and the first mask pattern 10 including the elongated patterns 10a and 10b which are more closely arranged.

As shown in FIG. 1B, surfaces of the elongated patterns 10a and 10b of the first and second pattern portions 10a′ and 10b′ which are adjacent to each other in the x-direction may partially contact each other. The elongated patterns 10a and 10b of the first and second pattern portions 10a′ and 10b′ may have different widths.

Referring to FIG. 1C, the mask pattern 1000c includes the holes 30 in a zigzag pattern. A plurality of the first mask patterns 10″ of the mask pattern 1000c may be intermittently formed in the x-direction, unlike in FIG. 1A. A first space S1 and a second space S2 may be respectively formed at centers of the first and second pattern portions 10a″ and 10b″ in the x-direction. In FIG. 1C, the first pattern portion 10a″ may include two columns of the elongated patterns 10b which are spaced apart from each other and are parallel to each other in the x-direction and the second pattern portion 10b″ may include two columns of the elongated patterns 10d which are spaced apart from each other and are parallel to each other in the x-direction. Also, a third space S3 may be formed between borders between the first and second pattern portions 10a″ and 10b″ in the x-direction.

Each of the elongated patterns 10b of the first pattern portion 10a″ may have a third length L3, and each of the elongated patterns 10d of the second pattern portion 10b″ may have a fourth length L4. The third length L3 and the fourth length L4 may be the same. In FIG. 1C, the first mask pattern 10″ may be formed by using only the elongated patterns 10c and 10d having the same length by adjusting lengths of the spaces S1, S2, and S3, unlike in FIG. 1A in which the elongated patterns 10a and 10b of the first and second pattern portions 10a′ and 10b′ may have different lengths.

Referring to FIG. 1D, the holes 30 are formed in zig-zag in a plurality of columns in the y-direction, unlike in FIGS. 1A through 1C, and adjacent columns are asymmetric with respect to each other. That is, the columns of the holes 30 may be repeatedly formed in the x-direction.

Elongated patterns 10e and 10g respectively having a fifth length L5 and a seventh length L7 may respectively constitute the first pattern portions 10a″′ and 10a″″ and elongated patterns 10f and 10h respectively having a sixth length L6 and a eighth length L8 may respectively constitute second pattern portions 10b′ and 10b″ ″. The fifth length L5 and a seventh length L7 may be the same, and the sixth length L6 and the eighth length L8 may be the same. The first lines 20a may be disposed on one end part of the first pattern portion 10a″′ and 10a″″ and the second lines 20b may be disposed one end parts of the first pattern portion 10b″′ and 10b″″ in the x-direction.

Referring to FIG. 1E, the mask pattern 1000e is similar to the mask pattern 1000a illustrated in FIG. 1A, except the second mask pattern 20′ of the mask pattern 1000e includes first 20c and second 20d elongated portions instead of the first 20a and second 20b lines shown in the mask pattern 1000a illustrated in FIG. 1A.

Referring to FIG. 1F, the mask pattern 1000f is similar to the mask pattern 1000a illustrated in FIG. 1A, except the second mask pattern 20″ of the mask pattern 1000e includes the second elongated portion 20d instead of the second 20b line of the mask pattern 1000a illustrated in FIG. 1A. Alternatively, the second mask pattern 20″ could include the first 20c elongated portion instead of the first line 20a (see FIG. 1A).

Since the mask patterns 1000a, 1000b, 1000c, and 1000d are patterned by using the first mask pattern 10, 10′, 10″, and 10″′ having a relatively short linear shape and the second mask pattern 20 having a relatively long linear shape in order to form the holes 30 having a checkered pattern instead of a lattice pattern, fine patterns may be uniformly formed.

FIGS. 2A through 9B are views illustrating a method of forming a fine pattern, according to example embodiments of inventive concepts.

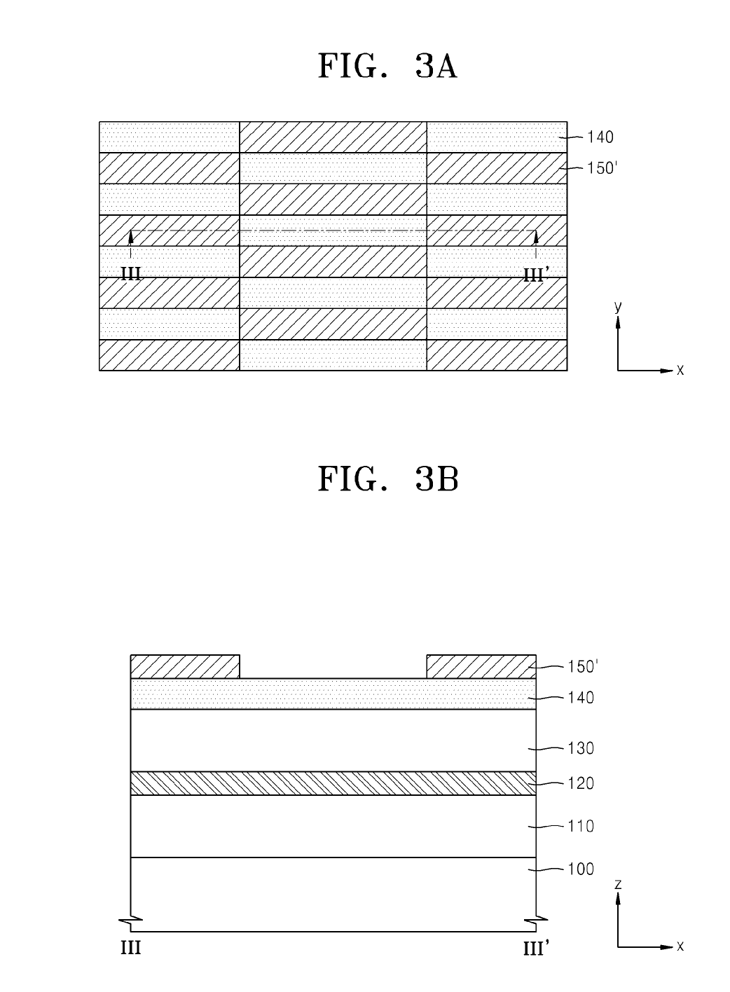

FIG. 2A is a plan view illustrating the portion P shown in FIG. 1A. FIG. 2B is a cross-sectional view taken along line II-II′ of FIG. 2A. FIGS. 3B, 4B, 5B, 6B, 7B, 8B, and 9B are cross-sectional views taken along lines III-III′, IV-IV′, V-V′, VI-VI′, VII-VII′, VIII-VIII′, and IX-IX′ of FIGS. 3A, 4A, 5A, 6A, 7A, 8A, and 9A respectively.

Referring to FIGS. 2A and 2B, a to-be-etched layer 110, a first hard mask layer 120, a second hard mask layer 130, a third hard mask layer 140, and a first mask layer 150 are sequentially formed on a substrate 100.

The substrate 100 may be a general semiconductor substrate such as a silicon substrate, but example embodiments are not limited thereto. The to-be-etched layer 110 may include, for example, a metal, a semiconductor, or an insulating material.

The first through third hard mask layers 120, 130, and 140 may be used as etch masks for the to-be-etched layer 110 and the first and second hard mask layers 120 and 130, respectively. In particular, the third hard mask layer 140 may be used as an etch-stop layer when the first mask layer 150 disposed on the third hard mask layer 140 is patterned.

The first through third hard mask layers 120, 130, and 140 may include materials having different etch selectivities. The term etch selectivity may refer to a ratio of a rate at which one layer is etched to a rate at which another layer is etched. For example, the first through third hard mask layers 120, 130, and 140 may include polysilicon, a carbon-containing material, and silicon oxide (SiO₂), respectively. In detail, the second hard mask layer 130 may be a layer formed of a hydrocarbon compound or a derivative thereof having a relatively high carbon content, namely, of about 85 to 99% by weight of carbon, such as an amorphous carbon layer (ACL) or a spin-on hard mask (SOH) layer.

The first through third hard mask layers 120, 130, and 140 may be formed by using a deposition process, for example, chemical vapour deposition (CVD) or atomic layer deposition (ALD), but example embodiments are not limited thereto. For example, if the second hard mask layer 130 is an ACL, the third hard mask layer 140 may be formed by using ALD in order to limit (and/or prevent) lifting due to a high-temperature process.

Materials and thicknesses of the first through third hard mask layers 120, 130, and 140 may be determined according to a material and a thickness of the to-be-etched layer 110. For example, the first hard mask layer 120 may have a thickness of about 900 Å, the second hard mask layer 130 may have a thickness of about 9000 Å, and the third hard mask layer 140 may have a thickness of about 500 Å. Alternatively, some of the first through third hard mask layers 120, 130, and 140 may be omitted. For example, only one hard mask layer may be formed.

The first mask layer 150 may include a material having an etch selectivity with respect to the third hard mask layer 140. For example, the first mask layer 150 may be formed of silicon nitride and may have a thickness of about 300 Å.

A first photoresist pattern 162 may be formed on the first mask layer 150. As shown in FIG. 2A, the first photoresist pattern 162 may be formed such that the first mask layer 150 is exposed in the first mask pattern 10, as described with reference to FIG. 1A. Although not shown in FIGS. 2A and 2B, an anti-reflective layer may be additionally formed between the first mask layer 150 and the first photoresist pattern 162.

Referring to FIGS. 3A and 3B, a portion of the first mask layer 150 exposed by the first photoresist pattern 162 is removed. If the first mask layer 150 is formed of silicon nitride, the portion of the first mask layer 150 exposed by the first photoresist pattern 162 may be removed by dry etching using CH₃F and CH₂F₂.

Due to the etching of the first mask layer 150, a first mask pattern 150′ may be formed. The first mask pattern 150′ may be formed such that a plurality of elongated openings are arranged in a checkered pattern at desired (or alternatively predetermined) intervals in the x and y axes. Although not shown in FIGS. 3A and 3B, due to the etching of the first mask layer 150, a portion of the third hard mask layer 140 may be recessed.

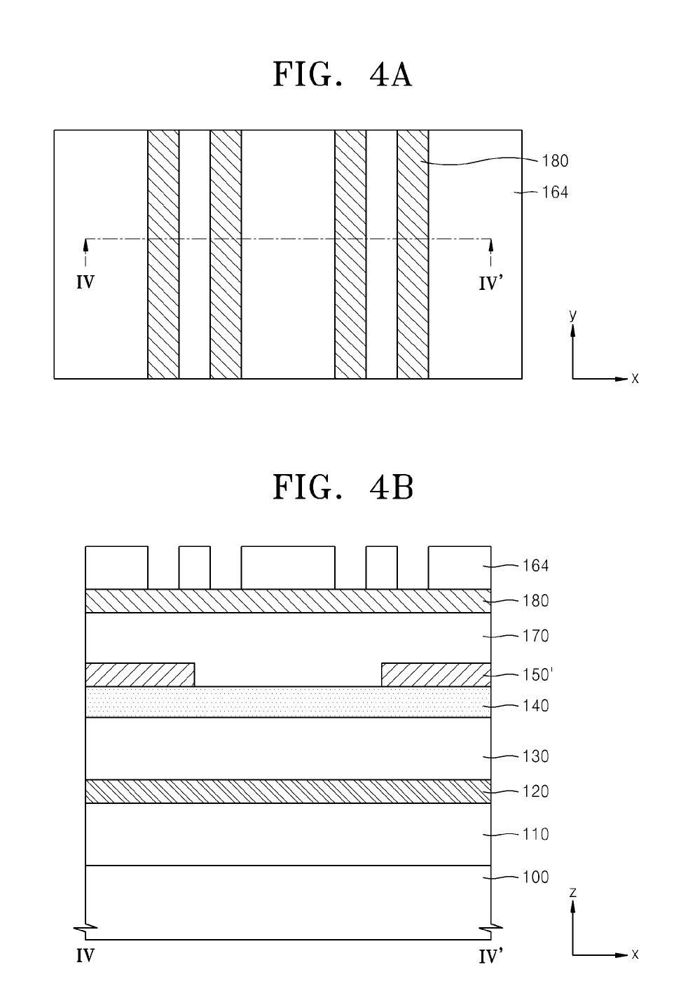

Referring to FIGS. 4A and 4B, a second mask layer 170 and an anti-reflective layer 180 may be sequentially formed on the first mask pattern 150′.

The second mask layer 170 may be deposited to a thickness greater than that of the first mask pattern 150′ to cover a stepped portion formed by the first mask pattern 150′ and to have a flat surface. The second mask layer 170 may be deposited to a thickness of, for example, 800 Å. The second mask layer 170 may be formed of a material having an etch selectivity with respect to the third hard mask layer 140 and the first mask pattern 150′. For example, the second mask layer 170 may be an SOH layer.

The anti-reflective layer 180 may reduce (and/or prevent) light from being reflected during photolithography and may be formed of silicon oxynitride (SiON).

Next, a second photoresist pattern 164 may be formed on the anti-reflective layer 180. The second photoresist pattern 164 may be formed such that the anti-reflective layer 180 is exposed in the second mask pattern 20, as described with reference to FIG. 1A. That is, the second photoresist pattern 164 may be formed such that linear openings extend in the y-direction and both lines formed over the first mask pattern 150′ and lines formed over portions other than the first mask pattern 150′ are included.

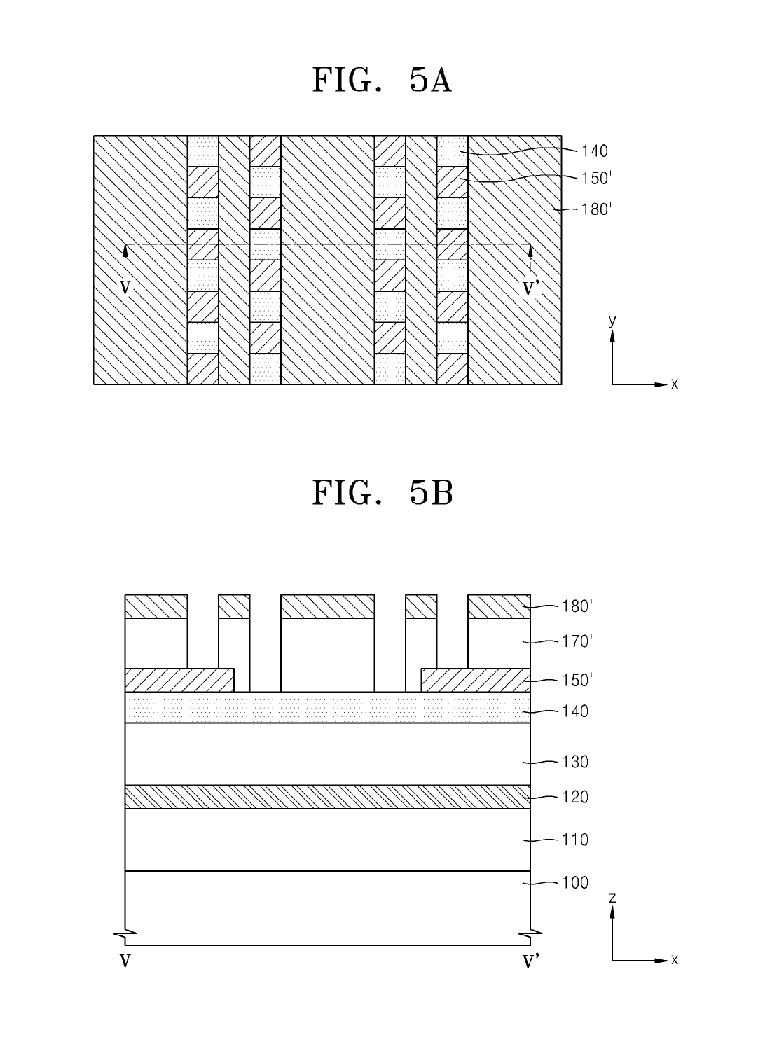

Referring to FIGS. 5A and 5B, portions of the anti-reflective layer 180 and the second mask layer 170 exposed by the second photoresist pattern 164 are removed. In this case, only the first mask layer 170 may be selectively etched so as not to etch the first mask pattern 150′ and the third hard mask layer 140 disposed under the second mask layer 170. The second mask layer 170 may be etched by using, for example, dry etching using oxygen plasma.

Accordingly, a second mask pattern 170′ and an anti-reflective pattern 180′ are formed, and a portion of the first mask pattern 150′ and a portion of the third hard mask layer 140 is exposed by the second mask pattern 170′. The first mask pattern 150′ and the third hard mask layer 140 are alternately exposed in the y-direction and are offset from each other in adjacent rows in the x-direction.

Alternatively, an order in which the first mask pattern 150′ and the second mask pattern 170′ are formed may be changed. That is, the second mask pattern 170′ including linear openings may be first formed, and then the first mask pattern 150′ including elongated openings may be formed.

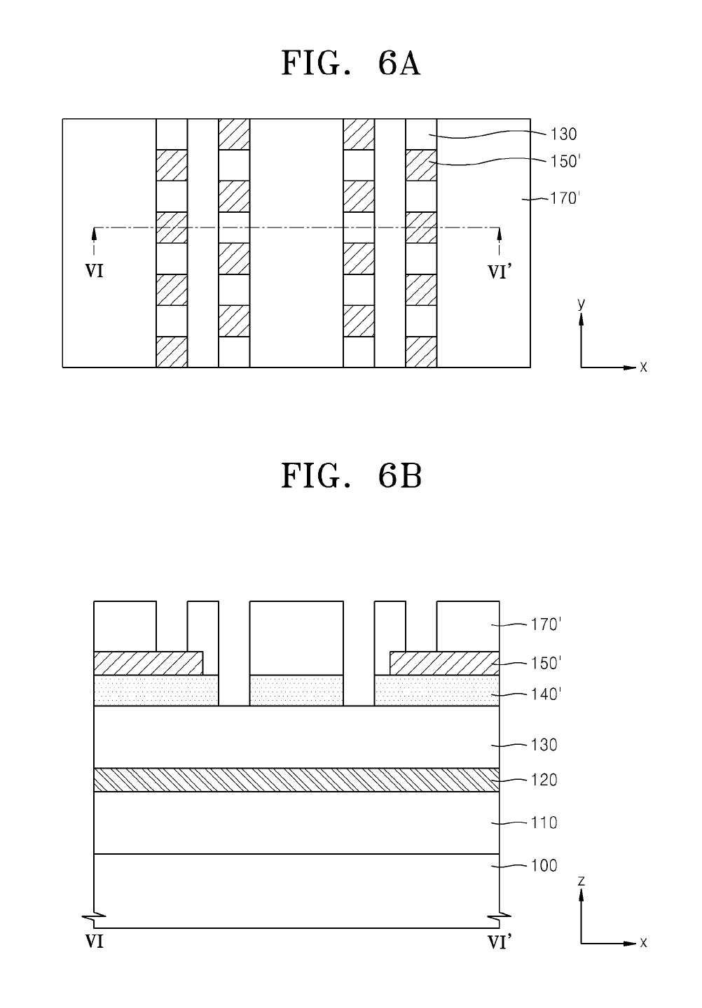

Referring to FIGS. 6A and 6B, a third hard mask pattern 140′ is formed by selectively removing the portion of the third hard mask layer 140 exposed by the second mask pattern 170′. While the portion of the third hard mask layer 140 is removed, the anti-reflective layer 180 disposed over the second mask pattern 170′ may be removed too.

While the portion of the third hard mask layer 140 is etched, the exposed portion of the first mask pattern 150′ may not be etched, or minimally etched so as not to expose the third hard mask layer 140 disposed under the first mask pattern 150′. To this end, the third hard mask layer 140 and the first mask pattern 150′ may have high etch selectivities as described above. In detail, a ratio (B/A) of a rate B at which the third hard mask layer 140 is etched to a rate A at which the first mask pattern 150′ is etched may be equal to or greater than 3.

Due to the removal, portions of the second hard mask layer 130 disposed under the third hard mask layer 140 may be exposed. The exposed portions of the second hard mask layer 130 may be arranged in a zigzag fashion in the y-direction, in the second mask pattern 170′ having a linear shape, as shown in FIG. 6A.

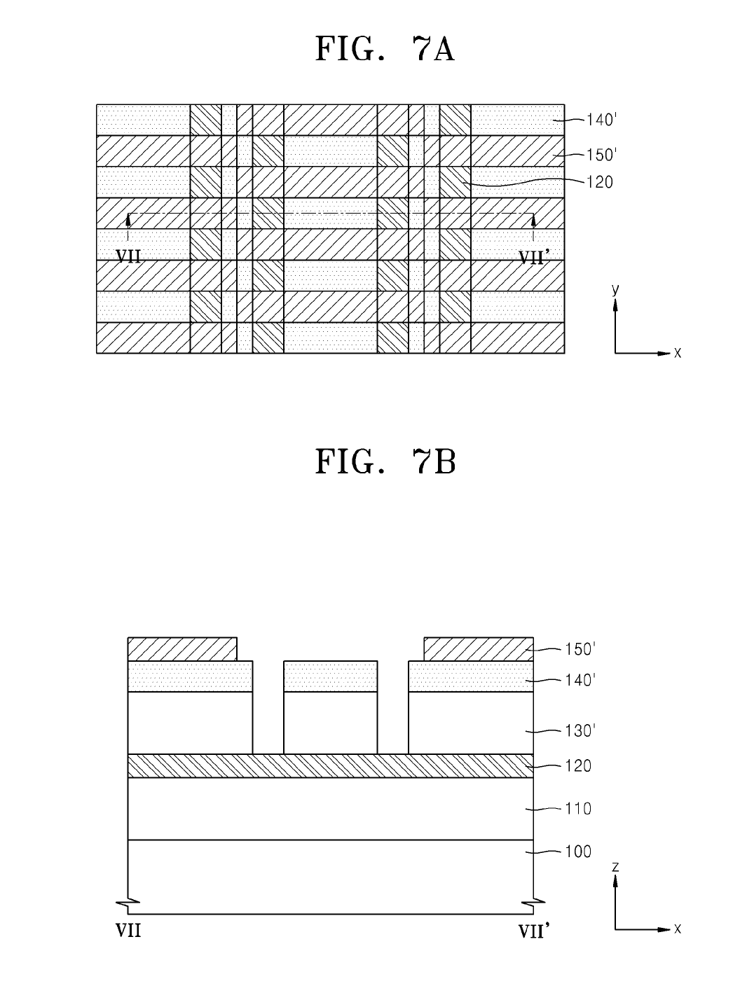

Referring to FIGS. 7A and 7B, a second hard mask pattern 130′ is formed by removing the exposed portions of the second hard mask layer 130 by using the third hard mask pattern 140′ as an etch mask. During the removal, the second mask pattern 170′ disposed over the first mask pattern 150′ may be removed too. For example, if the second mask pattern 170′ and the second hard mask layer 130 are carbon-containing layers, the second mask pattern 170′ and the second hard mask layer 130 may have similar etch selectivities.

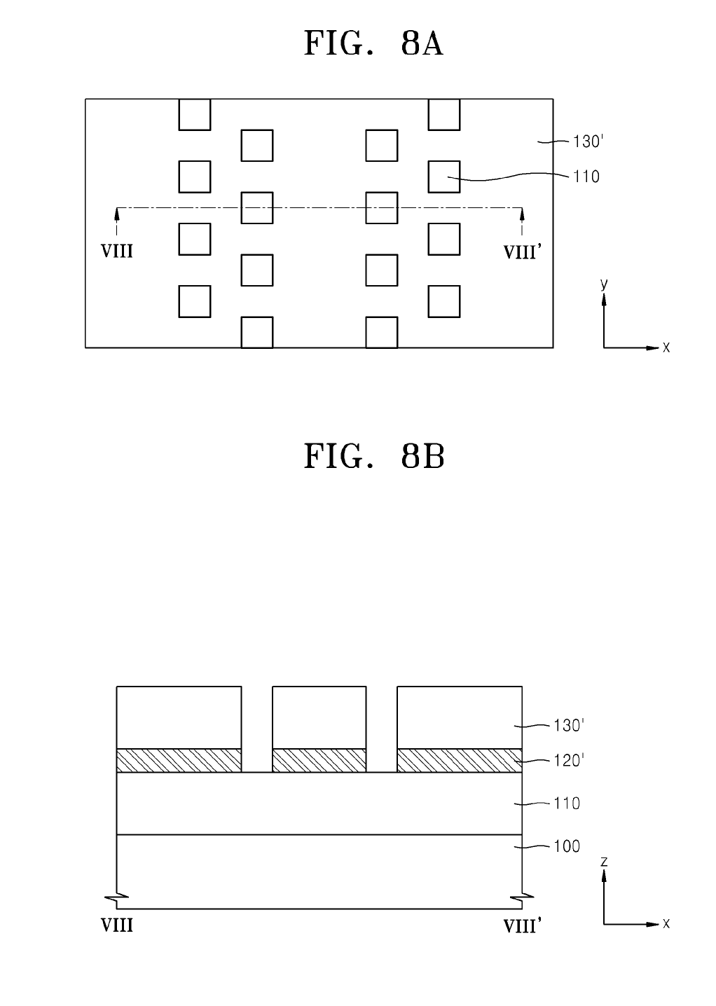

Referring to FIGS. 8A and 8B, an exposed portion of the first hard mask layer 120 is removed by using the second hard mask pattern 130′ as an etch mask. While the first hard mask layer 120 is etched, the third hard mask pattern 140′ and the first mask pattern 150′ disposed on the second hard mask pattern 130′ may be removed in situ or by using a separate process, in order to limit (and/or prevent) lifting when lower layers are etched in a subsequent process.

Accordingly, as shown in FIG. 8A, a second hard mask pattern 130′ and a first hard mask pattern 120′ are formed. The second hard mask pattern 130′ and the first hard mask pattern 120′ include a plurality of holes arranged in a zigzag fashion in the y-direction. Although the second hard mask pattern 130′ and the first hard mask pattern 120′ include quadrangular holes in FIG. 8A, example embodiments are not limited thereto and the holes may have circular, oval, or polygonal shapes.

Referring to FIGS. 9A and 9B, the to-be-etched layer 110 is etched by using the second hard mask pattern 130′ and the first hard mask pattern 120′ as an etch mask. While the to-be-etched layer 110 is etched, the second hard mask pattern 130′ may be partially removed. In particular, if the to-be-etched layer 110 has a high thickness, the second hard mask pattern 130 may be mostly etched and removed while the to-be-etched layer 110 is etched. Accordingly, the first hard mask pattern 120′ is formed of a material having a high etch selectivity with respect to the to-be-etched layer 110.

Last, only the to-be-etched layer 110 which is patterned to form the to-be-etched pattern 110′ is left by removing the second hard mask pattern 130 and the first hard mask pattern 120′. A plurality of holes arranged in a zigzag fashion in the y-direction are formed in the to-be-etched pattern 110′ as shown in FIG. 9A.

According to the method of FIGS. 2A through 9B, since holes are formed by using two mask patterns having linear openings, that is, the first mask pattern 150′ and the second mask pattern 170′, uniform patterning may be performed even when holes having sizes equal to or less than, for example, 100 nanometers, are formed in columns asymmetrically.

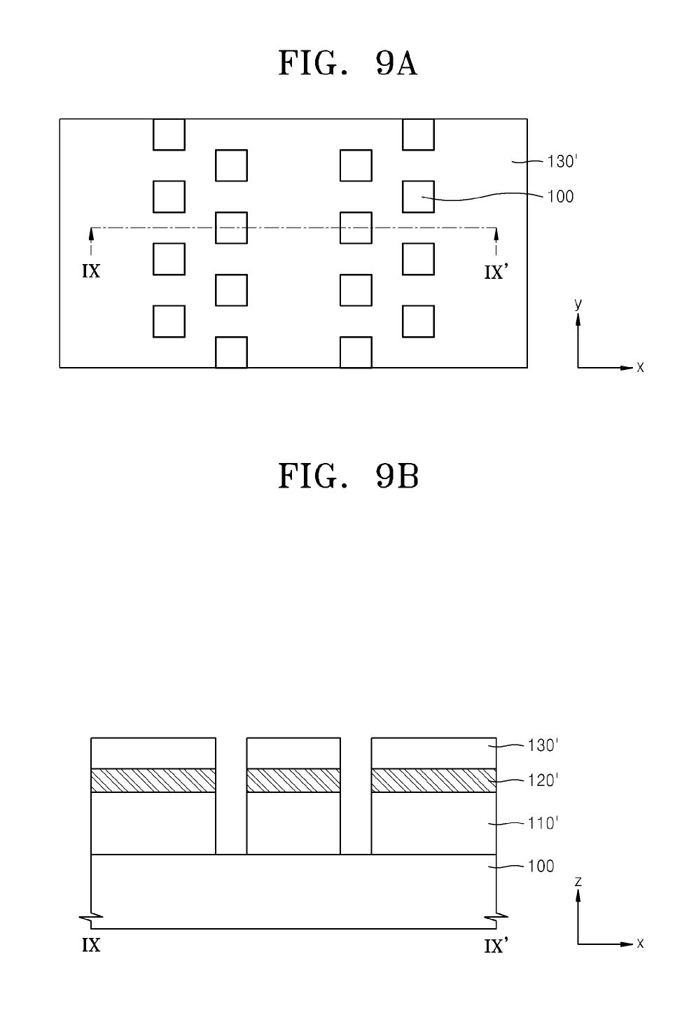

FIG. 10 is an equivalent circuit diagram illustrating a memory cell array 2 of a semiconductor device manufactured by the method of FIGS. 2A through 9B. A NAND flash memory device having a vertical channel structure is illustrated in FIG. 10.

Referring to FIG. 10, the memory cell array 2 may include memory cell strings 21. Each of the memory cell strings 21 may have a vertical structure extending in a direction (that is, the z-direction) perpendicular to extension directions (that is, the x and y-directions) in which a main surface of a substrate (not shown) extends. The memory cell strings 21 may constitute memory cell blocks 23.

Each of the memory cell strings 21 may include memory cells MC1 through MCn, a string select transistor SST, and a ground select transistor GST. In each of the memory cell strings 21, the ground select transistor GST, the memory cells MC1 through MCn, and the string select transistor SST may be disposed in series in a vertical direction (that is, the z-direction). The memory cells MC1 through MCn may store data. Word lines WL1 through WLn may be connected to the memory cells MC1 through MCn and control the memory cells MC1 through MCn. The number of memory cells MC1 through MCn may be appropriately determined according to a capacity of the semiconductor device.

Bit lines BL1 through BLm, which extend in the x-direction, may be connected to one of the ends of the memory cell strings 21, for example, drains of the string select transistors SST, arranged in first through mth columns of the memory cell block 23. Also, a common source line CSL may be connected to the other ends of the memory cell strings 21, for example, sources of the ground select transistors GST.

The word lines WL1 through WLn, which extend in the y-direction, may be commonly connected to gates of the memory cells MC1 through MCn arranged on the same row from among the memory cells MC1 through MCn of the memory cell strings 21. As the word lines WL1 through WLn are driven, data may be programmed to, read, or removed from the memory cells MC1 through MCn.

The string select transistors SST of the memory cell strings 21 may be disposed between the bit lines BL1 through BLm and the memory cells MC1 through MCn. The string select transistors SST in each of the memory cell blocks 23 may control data transfer between the bit lines BL1 through BLm and the memory cells MC1 through MCn due to string select lines SSL1 and SSL2 connected to gates of the string select transistors SST.

The ground select transistors GST may be disposed between the memory cells MC1 through MCn and the common source line CSL. The ground select transistors GST in each of the memory cell blocks 23 may control data transfer between the memory cells MC1 through MCn and the common source line CSL due to ground select lines GSL1 and GSL2 connected to gates of the ground select transistors GST.

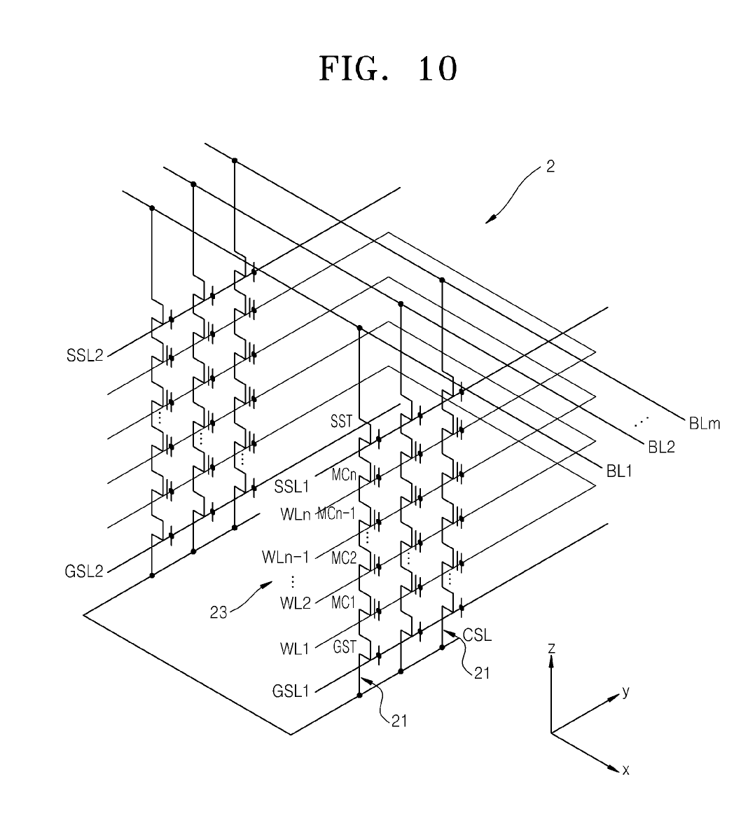

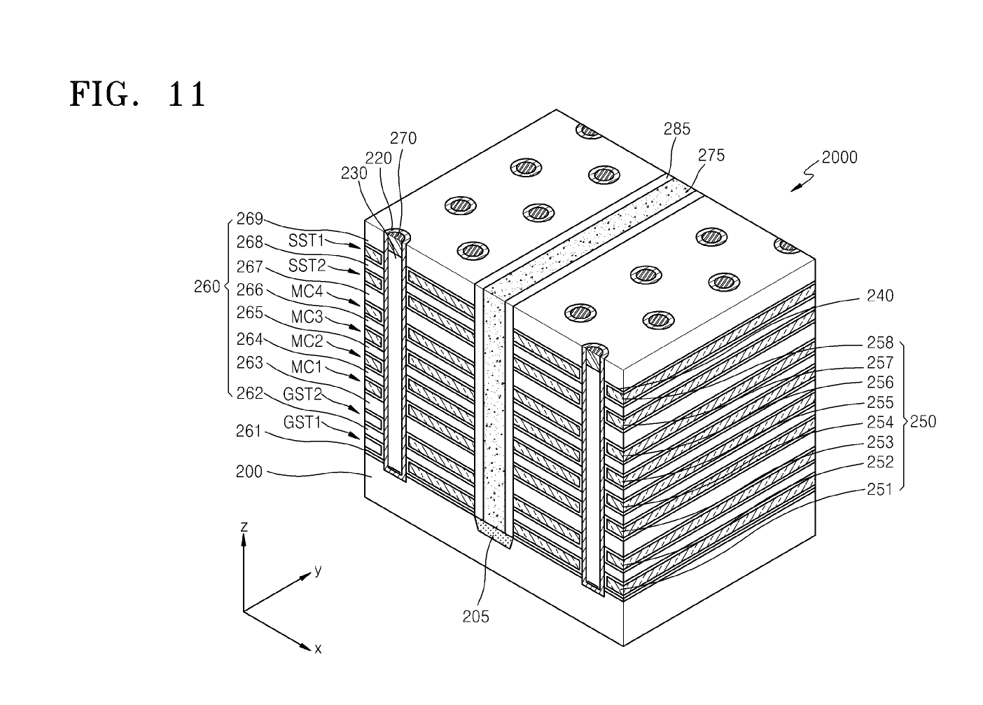

FIG. 11 is a perspective view illustrating a three-dimensional (3D) structure of memory cell strings 21 of a semiconductor device 2000 according to example embodiments of inventive concepts.

In FIG. 11, some elements constituting the memory cell string 21 of FIG. 10 may not be shown. For example, bit lines of the memory cell string 21 are not shown.

Referring to FIG. 11, the semiconductor device 2000 includes channel regions 220 disposed on a substrate 200, and memory cell strings disposed along side walls of the channel regions 220. The memory cell strings may be arranged in the y-direction along the side walls of the channel regions 220 that extend in the y-direction. As shown in FIG. 11, the memory cell strings 21 (see FIG. 10) extending in the z-direction from the substrate 200 may be arranged along side surfaces of the channel regions 220. Each of the memory cell strings 21 may include two ground select transistors GST1 and GST2, memory cells MC1, MC2, MC3, and MC4, and two string select transistors SST1 and SST2.

The substrate 200 may have a main surface that extends in the x-direction and the y-direction. The substrate 200 may include a semiconductor material, for example, a group IV semiconductor, a group III-V compound semiconductor, or a group II-VI oxide semiconductor. For example, examples of the group IV semiconductor may include silicon, germanium, and silicon-germanium. The substrate 200 may be provided as a bulk wafer or an epitaxial layer.

The channel regions 220 having pillar shapes may be formed on the substrate 200 to extend in the z-direction. The channel regions 220 may be spaced apart from one another in the x and y-directions. For example, the channel regions 220 may be disposed in a zigzag fashion in the y-direction. Although the channel regions 220 are disposed in a zigzag fashion in two columns in FIG. 11, example embodiments are not limited thereto and the channel regions 220 may be disposed in a zigzag fashion in three or more columns. The channel regions 220 may be formed to have, for example, annular shapes. Bottom surfaces of the channel regions 220 may directly contact the substrate 200 and thus the channel regions 220 may be electrically connected to the substrate 200. Each of the channel regions 220 may include a semiconductor material such as polycrystalline silicon or monocrystalline silicon, and the semiconductor material may be undoped or doped with p-type or n-type impurities. A buried insulating layer 230 may be formed in the channel region 220. The channel regions 220 which are adjacent to each other with a common source line 275 therebetween may be symmetric as shown in FIG. 11, but example embodiments are not limited thereto.

A plurality of the string select transistors SST1 and SST2 arranged in the x-direction may be commonly connected to the bit lines BL1 through BLm (see FIG. 10). Also, a plurality of the ground select transistors GST1 and GST2 arranged in the x-direction may be electrically connected to impurity regions 205 adjacent to the ground select transistors GST1.

The impurity regions 205 may be arranged adjacent to the main surface of the substrate 200 to extend in the y-direction and to be spaced apart from one another in the x-direction. The impurity regions 205 may be source regions and may form PN junction with other regions of the substrate 200.

The common source line 275 may be disposed on each of the impurity regions 205 to extend in the z-direction and to come in ohmic contact with the impurity regions 205. The common source line 275 may provide source regions to the ground select transistors GST1 and GST2 of the memory cell strings disposed along side surfaces of two channel regions 220 which are adjacent to each other in the x-direction. The common source line 275 may extend in the y-direction along the impurity region 205. The common source line 275 may include a conductive material. For example, the common source line 275 may include any one metal material selected from the group consisting of tungsten (W), aluminium (Al), and copper (Cu). Although not shown in FIG. 11, a silicide layer may be disposed between the impurity region 205 and the common source line 275 in order to reduce contact resistance. Insulating regions 285 having spacer shapes may be formed on both side surfaces of the common source line 275.

Gate electrodes 251 through 258, which are collectively denoted by 250, may be arranged along the side surface of the channel region 120 to be spaced apart from one another in the z-direction from the substrate 200. The gate electrodes 250 may be gate electrodes of the ground select transistors GST1 and GST2, the memory cells MC1, MC2, MC3, and MC4, and the string select transistors SST1 and SST2. The gate electrodes 250 may be commonly connected to memory cell strings which are arranged adjacent to each other in the y-direction. The gate electrodes 257 and 258 of the string select transistors SST1 and SST2 may be connected to the string select line SSL (see FIG. 10). The gate electrodes 253, 254, 255, and 256 of the memory cells MC1, MC2, MC3, and MC4 may be connected to the word lines WL1, WL2, WLn-1, and WLn (see FIG. 10). The gate electrodes 251 and 252 of the ground select transistors GST1 and GST2 may be connected to the ground select line GSL (see FIG. 10). The gate electrodes 250 may include a metal, for example, tungsten (W). Also, although not shown in FIG. 11, the gate electrodes 250 may further include a diffusion barrier layer (not shown). For example, the diffusion barrier layer may include any one selected from the group consisting of tungsten nitride (WN), tantalum nitride (TaN), and titanium nitride (TiN).

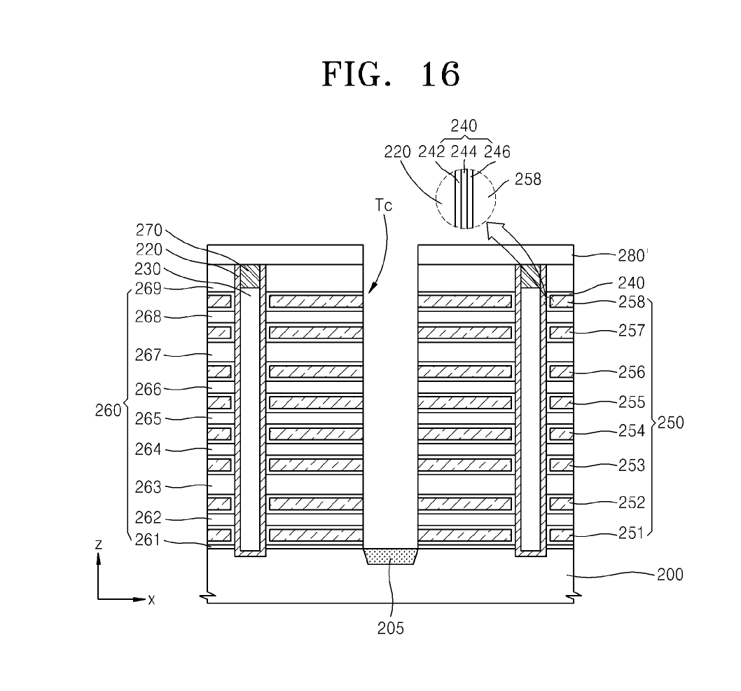

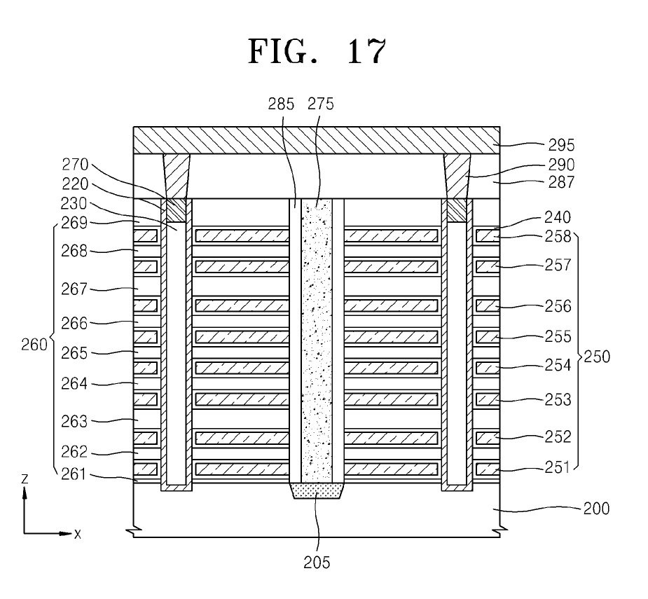

A gate dielectric layer 240 may be disposed between the channel region 220 and the gate electrodes 250. Although not shown in FIG. 11, the gate dielectric layer 240 may include a tunnelling insulating layer 242 (see FIG. 16), a charge storage layer 244 (see FIG. 16), and a blocking insulating layer 246 (see FIG. 16), which are sequentially stacked from the channel region 220.

Interlayer insulating layers 261 through 269, which are collectively denoted by 260, may be disposed between the gate electrodes 250. The interlayer insulating layers 260 may be arranged to be spaced apart from one another in the z-direction and to extend in the y-direction, like the gate electrodes 250. One of the side surfaces of the interlayer insulating layers 260 may contact the channel region 220. The interlayer insulating layers 260 may include silicon oxide or silicon nitride.

Although four memory cells, that is, the memory cells MC1, MC2, MC3, and MC4, are arranged in FIG. 11, example embodiments are not limited thereto and more or less memory cells may be arranged according to a capacity of the semiconductor device 2000. Also, the string select transistors SST1 and SST2 and the ground select transistors GST1 and GST2 of the memory cell strings each make a pair. If the number of string select transistors and ground select transistors is 2 or more, gate lengths of the select gate electrodes 251, 252, 257, and 258 may be much smaller than gate lengths when one string select transistor and one ground select transistor is formed, thereby filling between the interlayer insulating layers 260 without voids. However, example embodiments are not limited thereto, and one string select transistor SST and one ground select transistor GST of the memory cell string may exist as shown in FIG. 10. Also, the string select transistor SST and the ground select transistor GST may have structures different from those of the memory cells MC1, MC2, MC3, and MC4.

FIGS. 12 through 17 are cross-sectional views illustrating a method of manufacturing the semiconductor device 2000 of FIG. 11, according to example embodiments of inventive concepts.

Referring to FIG. 12, interlayer sacrificial layers 211 through 218, which are collectively denoted by 210, and the interlayer insulating layers 261′ through 269′, which are collectively denoted by 260′, are alternately stacked on the substrate 200. The interlayer sacrificial layers 210 and the interlayer insulating layers 260′ may be alternately stacked on the substrate 200 beginning with the interlayer insulating layer 261′. The interlayer sacrificial layers 210 may be formed of a material which may be etched at an etch selectivity with respect to the interlayer insulating layers 260′. That is, the interlayer sacrificial layers 210 may be formed of a material which may be etched to minimally etch the interlayer insulating layers 260′. For example, the interlayer insulating layers 260′ may be at least one of the group consisting of silicon oxide layers and silicon nitride layers, and the interlayer sacrificial layers 210, which are formed of a material different from that of the interlayer insulating layers 260′, may be one selected from the group consisting of silicon layers, silicon oxide layers, silicon carbide, and silicon nitride layers.

As shown in FIG. 12, thicknesses of the interlayer insulating layers 260′ may not be the same. Thicknesses of the interlayer insulating layers 260′ and the interlayer sacrificial layers 210 may vary, and the number of layers constituting each of the interlayer insulating layers 260′ and the interlayer sacrificial layers 210 may vary.

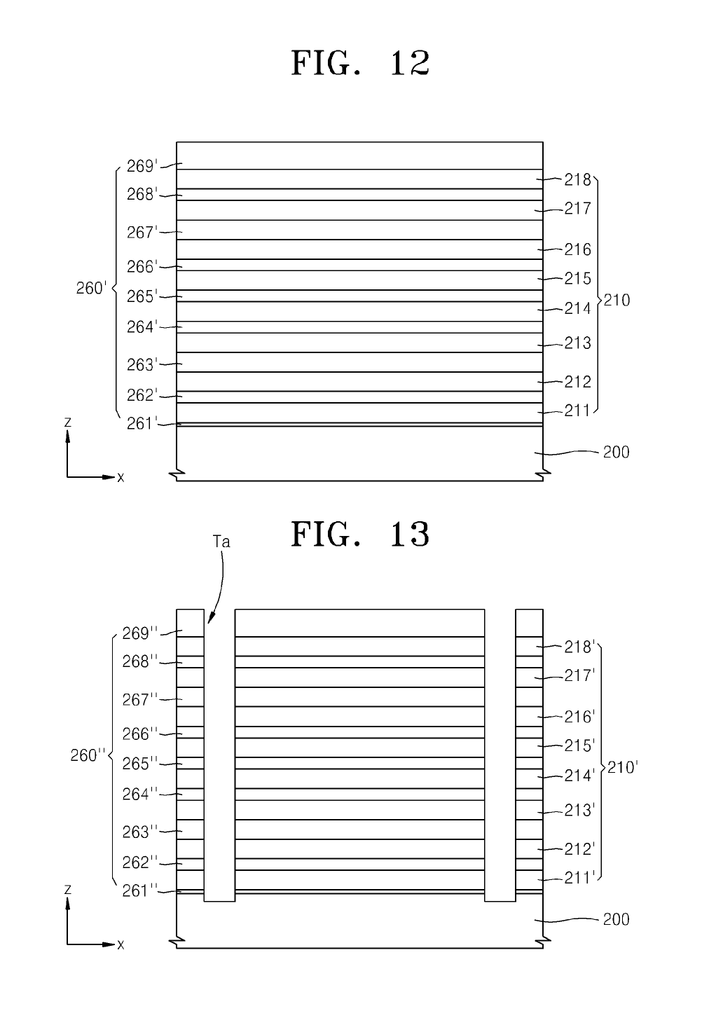

Referring to FIG. 13, first openings Ta passing through the interlayer insulating layers 260′ and the interlayer sacrificial layers 210 may be formed. As a result, interlayer insulating layers 261″ through 269″, which are collectively denoted by 260″, and interlayer sacrificial layers 211′ to 218′, which are collectively denoted by 210′ may result. The first openings Ta may be holes having depths in the z-direction. Also, the first openings Ta may be isolated openings that are spaced apart from one another in the x and y-directions (see FIG. 11).

The first openings Ta may be formed by using the method of FIGS. 2A through 9B. In this case, the interlayer insulating layers 260′ and the interlayer sacrificial layers 210 correspond to the to-be-etched layer 110 of FIG. 2A. Also, considering etch selectivities of the interlayer insulating layers 260′ and the interlay sacrificial layers 210, the first through third hard mask layers 120, 130, and 140 of FIG. 2A may be formed of polysilicon, a carbon-containing material, and silicon oxide (SiO₂), respectively. Accordingly, the first openings Ta may be formed to have uniform sizes of 60 to 80 nm.

Although not shown in FIG. 13, since a structure including different layers is etched, side walls of the first openings Ta may not be perpendicular to a top surface of the substrate 200. For example, the first openings Ta closer to the substrate 200 may have smaller widths.

The first openings Ta may be formed to expose the top surface of the substrate 200, as shown in FIG. 13. In addition, as a result of over-etching during anisotropic etching, portions of the substrate 200 under the first openings Ta may be recessed to desired (or alternatively predetermined) depths.

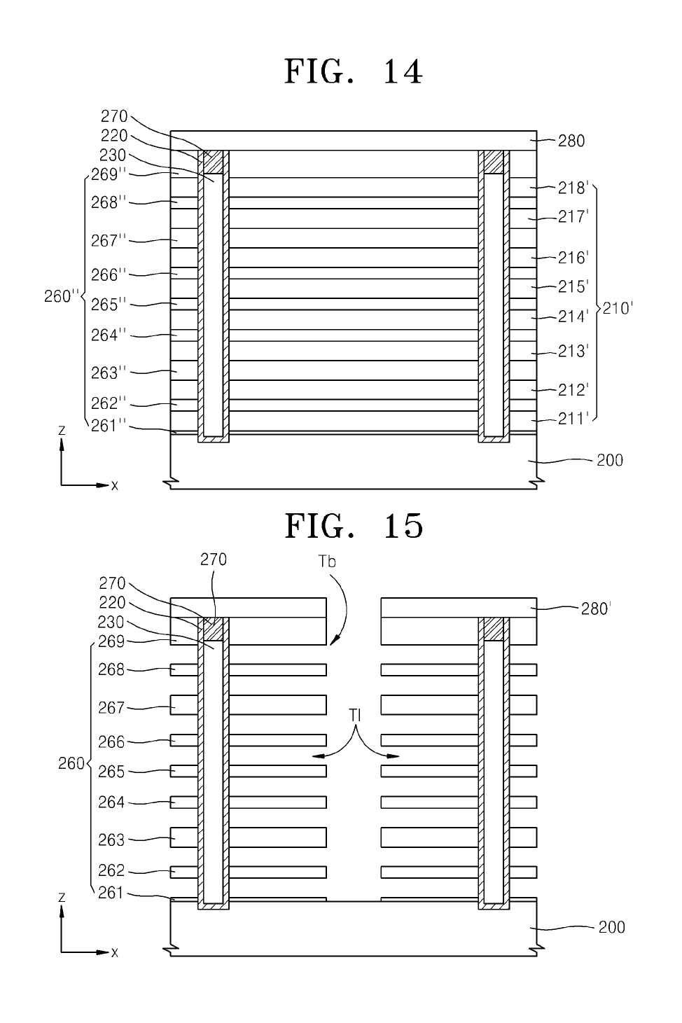

Referring to FIG. 14, the channel regions 220 may be formed to uniformly cover inner walls and bottom surfaces of the first openings Ta. The channel regions 220 may be formed by directly depositing polycrystalline silicon or depositing amorphous silicon, and crystallizing the amorphous silicon through a heat treatment into polycrystalline silicon. The channel regions 220 may be formed to a desired (or alternatively predetermined) thickness which is, for example, 1/50 to ⅕ of the widths of the first openings Ta, by using ALD or CVD. The channel regions 220 on bottom surfaces of the first openings Ta may directly contact the substrate 200 to be electrically connected to the substrate 200.

Next, the first openings Ta may be filled with the buried insulating layer 230. Next, planarization may be performed to remove an unnecessary semiconductor material or insulating material which covers the interlayer insulating layer 269″, which is the uppermost interlayer insulating layer. Next, an upper portion of the buried insulating layer 230 may be partially removed by etching such as etch-back.

Next, a material for forming the conductive layer 270 may be deposited on a position from which the upper portion of the buried insulating layer 230 is removed. Next, the conductive layer 270 may be formed by performing planarization. After the conductive layer 270 is formed, an upper insulating layer 280 may be formed on the interlayer insulating layer 269″, which is a ninth interlayer insulating layer.

Referring to FIG. 15, second openings Tb through which the substrate 200 is exposed may be formed. The second openings Tb may extend in the y-direction (see FIG. 11). The second openings Tb may be formed such that one second opening Tb is formed between two channel regions 220, as shown in FIG. 15. However, example embodiments are not limited thereto, and the channel regions 220 and the second openings Tb may be arranged in other ways.

The second openings Tb may be formed by anisotropically etching the upper insulating layer 280, the interlayer insulating layers 260″, and the interlayer sacrificial layers 210′ by using photolithography and etching. As a result of the photolithography and etching, the interlayer insulating layers 261 to 269, which are collectively denoted by 260, and the upper insulating layer 280′ result. The interlayer sacrificial layers 210′ exposed through the second openings Tb may be removed by etching, and thus side openings T1 defined between the interlayer insulating layers 260 may be formed. Side walls of the channel region 220 may be partially exposed through the side openings T1.

Referring to FIG. 16, the gate dielectric layer 240 may be formed to uniformly cover the channel regions 220 and the interlayer insulating layers 260, and the substrate 200 exposed through the side openings T1.

The gate dielectric layer 240 may include the tunneling insulating layer 242, the charge storage layer 244, and the blocking insulating layer 246, which are sequentially stacked from the channel regions 220. The tunneling insulating layer 242, the charge storage layer 244, and the blocking insulating layer 246 may be formed by using ALD, CVD, or physical vapor deposition (PVD).

Next, a portion of the second openings Tb and the side openings T1 may be filled with a conductive material. Next, third openings Tc may be formed by partially etching the conductive material. Accordingly, the conductive material is filled in only the side openings T1 to form the gate electrodes 250. The third openings Tc may be formed by anisotropic etching, and portions of the gate dielectric layer 240 formed on top surfaces of the substrate 200 and the upper insulating layer 280′ may be removed by anisotropic etching. Portions of the gate dielectric layers 240 formed on side surfaces of the interlayer insulating layers 260 may also be removed. Selectively, the portions of the gate dielectric layers 240 formed on the side surfaces of the interlayer insulating layers 260 may not be removed. Next, the impurity regions 205 may be formed by injecting impurities into the substrate 200 through the third openings Tc.

Referring to FIG. 17, the insulating regions 285 and the common source line 275 filled in the third openings Tc may be formed. The insulating regions 285 may be formed by filling an insulating material in the third openings Tc and then performing anisotropic etching. The insulating regions 285 may be formed of the same material as the interlayer insulating layers 260. Next, the common source line 275 may be formed by depositing a conductive material and performing etch-back.

Next, impurities may be injected to form the string select transistors SST1 and SST2 (see FIG. 11) of the memory cell string formed along the channel region 220. The injecting of the impurities is optional and may be omitted, and may be performed in other processes.

Next, a wire insulating layer 287 may be formed on the interlayer insulating layer 269, which is a ninth interlayer insulting layer, and on the common source line 275, and bit line contact plugs 290 passing through the wire insulating layer 287 may be formed. The bit line contact plugs 290 may be formed by forming contacts by photolithography and etching, and depositing a conductive material in the contacts.

Next, a bit line 295, which connects the bit line contact plugs 290 arranged in the x-direction, may be formed on the wire insulating layer 287. The bit line 295 may also be formed to have a linear shape by performing deposition, photolithography, and etching.

While some example embodiments of inventive concepts have been particularly shown and described, it will be understood that various changes in form and details may be made therein without departing from the spirit and scope of the following claims.

What is claimed is:

1. A method of forming a fine pattern, the method comprising:
forming a hard mask layer on a to-be-etched layer;
forming a first mask pattern on the hard mask layer,
the first mask pattern defining a plurality of elongated openings that are arranged at intervals in a first direction and a second direction different from the first direction and are offset from each other in adjacent columns in the second direction;
forming a second mask pattern on the hard mask layer,
the second mask pattern defining at least two linear openings that each pass through the elongated openings of the first mask pattern and extend in the first direction;
forming a hard mask pattern by etching the hard mask layer using the second mask pattern as an etch mask; and
etching the to-be-etched layer using the hard mask pattern as another etch mask.

2. The method of claim 1, wherein
the plurality of elongated openings are elongated in the second direction, and
the first mask pattern includes a chess board-like arrangement due to the plurality of elongated openings.

3. The method of claim 1, wherein
the first mask pattern includes a first pattern portion and a second pattern portion adjacent to the first pattern portion,
each of the first pattern portion and the second pattern portion define one column of the plurality of elongated openings arranged at intervals in the first direction, and
the first pattern portion and the second pattern portion are alternately arranged in the second direction.

4. The method of claim 3, wherein, in the first mask pattern, the plurality of elongated openings of the first pattern portion and the plurality of elongated openings of the second pattern portion have different lengths in the second direction.

5. The method of claim 3, wherein the second mask pattern is on end portions of the first pattern portion and the second pattern portion in the second direction.

6. The method of claim 1, wherein
the first mask pattern includes a stepped portion, and
the second mask pattern is thick enough to cover the stepped portion of the first mask pattern.

7. The method of claim 1, wherein the second mask pattern exposes a portion of the hard mask layer and a portion of the first mask pattern.

8. The method of claim 1, wherein
the forming the hard mask pattern includes forming apertures in portions of the hard mask layer exposed by both the first mask pattern and the second mask pattern, and
the etching of the to-be etched layer includes forming holes in portions of the to-be etched layer exposed by the hard mask pattern.

9. The method of claim 8, wherein the holes of the to-be etched layer are arranged in a zigzag fashion in the first direction.

10. The method of claim 1, wherein the first mask pattern, the second mask pattern, and the hard mask layer include materials having etch selectivities with respect to one another.

11. The method of claim 1, wherein
the hard mask layer comprises silicon oxide,
the first mask pattern comprises silicon nitride, and
the second mask pattern comprises a carbon-containing material.

12. The method of claim 1, wherein
the forming of the first mask pattern includes forming a first mask layer and forming an anti-reflective layer on the first mask layer, and
the forming of the second mask pattern includes forming a second mask layer and forming an anti-reflective layer on the second mask layer.

13. A method of manufacturing a semiconductor device, the method comprising:
alternately stacking interlayer sacrificial layers and interlayer insulating layers on a substrate;
forming first openings, which pass through the interlayer sacrificial layers and the interlayer insulating layers to be connected to the substrate, by using the method of claim 1; and
forming channel regions in the first openings.

14. The method of claim 13, further comprising:
forming buried insulating layers in the channel regions to fill the first openings;
forming second openings, which pass through the interlayer sacrificial layers and the interlayer insulating layers to be connected to the substrate, between the channel regions;
forming side openings by removing portions of the interlayer sacrificial layers exposed through the second openings,
the side openings extending from the second openings to partially expose the channel regions and interlayer insulating layers;
forming gate dielectric layers in the side openings; and
forming gate electrodes comprising a memory cell transistor electrode and a select transistor electrode on the gate dielectric layers to cover the side openings.

15. The method of claim 13, wherein the hard mask layer comprises:
a first hard mask layer containing polysilicon and on the alternating stack of the interlayer sacrificial layers and the interlayer insulating layers;
a second hard mask layer containing a carbon-containing material and on the first hard mask layer; and
a third hard mask layer containing silicon oxide and on the second hard mask layer.

16. A method of forming a fine pattern, comprising:
forming a first mask pattern on a lower structure,
the first mask pattern including at least one first pattern portion,
the first pattern portion defining a plurality of first openings that are spaced apart from each other at intervals in a first direction and elongated in a second direction,
the first and the second direction being non-parallel;
forming a second mask pattern on the first mask pattern,
the second mask pattern defining a plurality of first linear openings,
each of the first linear openings being elongated in the first direction and intersecting at least one of the first openings of the first mask pattern; and
etching a portion of the lower structure exposed where the first linear openings of the second mask pattern intersect the first openings of the first mask pattern.

17. The method of claim 16, wherein
the lower structure includes at least one hard mask film on a to-be etched layer, and
the etching a portion of the lower structure includes,
forming a hard mask pattern by etching through the at least one hard mask film by using the second mask pattern as an etch mask, and
etching the portions of the to-be etched layer by using the hard mask pattern as another etch mask.

18. The method of claim 16, wherein
the first mask pattern includes,
a plurality of the first pattern portions, and
a plurality of second pattern portions arranged in between the plurality of first pattern portions along the second direction,
each second pattern portion defining a plurality of second openings that are spaced apart from each other at intervals in the first direction, elongated in the second direction, and offset along the first direction from the first openings in adjacent first pattern portions;
the second mask pattern includes a plurality of second linear openings,
each of the second linear openings being elongated in the first direction and intersecting at least one of the second openings of the second mask pattern; and
the method further includes etching a part of the lower structure exposed where the second linear openings of the second mask pattern intersect the second openings of the first mask pattern.

19. The method of claim 16, wherein the method includes etching the portion of the lower structure and the part of the lower structure simultaneously.

20. A method of forming pillar openings comprising:
alternately stacking interlayer sacrificial layers and interlayer insulating layers on a substrate;
using the method of claim 19 to form a plurality of first and second pillar openings through the interlayer sacrificial layers and the interlayer insulating layers to expose regions of the substrate,
the lower structure corresponding to the interlayer sacrificial layers and interlayer insulating layers alternately stacked on the substrate,
the first pillar openings corresponding to the portion of the lower structure etched where the first linear openings of the second mask pattern intersect the first openings of the first mask pattern, and
the second pillar openings corresponding to the part of the lower structure etched where the second linear openings of the second mask pattern intersect the second openings of the first mask pattern.
